(19) United States
(12) Patent Application Publication
(10) Pub. No.: US 2026/0173502 A1
(43) Pub. Date: Jun. 18, 2026

(54) SIC DOUBLE GATE TRENCH MOSFET WITH EMBEDDED SUPPER BARRIER RECTIFIER HAVING SHORT CHANNEL

(71) Applicant: Nami MOS CO., LTD., New Taipei City (TW)

(72) Inventors: FU-YUAN HSIEH, New Taipei City (TW); LIN XU, SHANGHAI (CN)

(73) Assignee: Nami MOS CO., LTD., New Taipei City (TW)

(21) Appl. No.: 18/985,705

(22) Filed: Dec. 18, 2024

(51) Int. Cl. H10D 84/00; H10D 8/60; H10D 30/66; H10D 62/10; H10D 62/832

(52) U.S. Cl. CPC H10D 84/146; H10D 8/605; H10D 30/668; H10D 62/105; H10D 62/8325

(57) ABSTRACT

A SiC power device cell having double gate trenches with a first gate channel region of a SiC MOSFET formed along at least one sidewall of a first type gate trench connecting to a first source region, and a second gate channel region of a SiC SBR which is a MOS channel diode formed along a sidewall of a second type gate trench connecting to a second source region to inactivate a parasitic body diode for the turn-off switching loss reduction. A first P-shield region surrounds a bottom region of the second type gate trench and is connected to a source metal through a sidewall P type region, and a second P-shield region adjoins a lower surface of the first body region forming a saturation current pinching region with an adjacent second P-shield region for short circuit capability enhancement and gate oxide electric field reduction.

### FIELD OF THE INVENTION

This invention relates generally to a unit cell structure of a semiconductor device having a double gate trench (DGT) structure, and more particularly, to integrate a SiC Metal Oxide Semiconductor Field Effect Transistor (MOSFET), and a novel SiC Super Barrier Rectifier (SBR) as a MOS-Channel Diode (MCD) having a short channel into the unit cell to achieve a lower on-resistance, a less switching loss and a higher short circuit capability, and further improve the safe operating area.

### BACKGROUND OF THE INVENTION

Because of their faster switching speed, higher temperature operation, and lower switching loss, SiC MOSFETs are very promising to replace Si super junction MOSFETs, and Si Insulated Gate Bipolar Transistors (IGBTs). However, a parasitic PIN body diode of the SiC MOSFET has a relatively higher turn-on voltage (˜3 V) than its Si MOSFET counterpart (˜0.7 V), owing to the wide band gap properties, which deteriorates reverse recovery characteristics. As a result, external Schottky barrier diodes (SBDs) are normally used in power modules to inactivate a parasitic PIN diode. However, it was found that the parasitic inductance between the MOSFET and the external SBD has a great effect on the conduction power loss.

Various integrated devices are suggested and demonstrated to improve the characteristics of the parasitic PIN body diode in the SiC MOSFETs. Among them, integrating with an SBD or a Junction barrier diode (JBSD) is widely adopted. However, a high-temperature reverse leakage current of the SBD is much larger than that of the parasitic PIN diode.

Therefore, there is still a need in the art of the SiC MOSFET design and fabrication, to provide a novel cell structure, device configuration and manufacturing process that making an SGT MOSFET have a lower on-resistance and a lower switching loss.

### SUMMARY OF THE INVENTION

The present invention provides an SGT MOSFET integrated with a novel super barrier rectifier (SBR) as a MOS-Channel diode having a short channel for reducing the switching loss. The integrated SBR creates a low potential barrier for the majority carrier in a MOS channel, which is adjustable by the gate oxide thickness, the P body doping concentration and the channel length. The SBR has a lower forward voltage V_{f} and a lower reverse leakage current Iᵣ than the Schottky Barrier rectifier. Moreover, the SBR has a better and reliable performance at elevated temperature than the SBD and JSBD.

The present invention discloses a SiC power device comprising a SiC MOSFET and a SiC SBR disposed in each unit cell having a DGT structure comprising: a first type gate trench for SiC MOSFET and a second type gate trench for SiC SBR; a first gate channel region of the SiC MOSFET formed in a first body region along at least one sidewall of the first type gate trench, and a second gate channel region of the SiC SBR formed in a second body region along a first sidewall of the second type gate trench; the SiC MOSFET has a first gate oxide, and the SiC SBR has a second gate oxide with a oxide thickness thinner than that of the first gate oxide; the SiC SBR has a channel length shorter than that of the SiC MOSFET; A first P-shield (PS) region surrounding a bottom region of the second type gate trench connecting to the first body region through a sidewall P type region adjacent to a second sidewall of the second type gate trench. The first PS region grounded to a source metal for the gate oxide electric field reduction, and a saturation current pitching (SCP) region formed between two adjacent second PS regions adjoining a lower surface of the first body region for the short circuit capability enhancement.

According to one aspect, the invention features a SiC power device further comprising a first gate electrode of a SiC MOSFET and a second gate electrode of a SiC SBR disposed in the first and second type gate trenches, respectively; the first gate electrode laterally isolated from the epitaxial layer by a first gate oxide of the SiC MOSFET, and the second gate electrode laterally isolated from the epitaxial layer by a second gate oxide, wherein the second gate oxide has a thickness less than that of the first gate oxide; and the second gate electrode shorted to a source metal through a gate contact of the SiC SBR.

According to another aspect, the invention features a SiC power device with a first type gate trench having a one-step gate trench structure in the SiC MOSFET comprising a top gate trench and a bottom gate trench; the top gate trench is disposed above the bottom gate trench with a trench width wider than that of the bottom gate trench; and the bottom gate trench is filled up with a thick oxide as a first insulating film.

According to another aspect, the invention features a SiC power device having a SiC MOSFET with least two-step gate oxide structure formed in the first type gate trench. The two-step gate oxide structure comprising a first top gate oxide and a first bottom gate oxide. The first top gate oxide is above the first bottom gate oxide along the first type gate trench and has a gate oxide thickness less than that of the first bottom gate oxide.

According to another aspect, the invention features a SiC power device further comprising: a first gate electrode disposed in an upper portion of the first type gate trench, and a shielded gate electrode disposed below the first gate electrode and isolated from each other by an inter-poly oxide (IPO) layer; the first gate electrode laterally isolated from the epitaxial layer by a first gate oxide of the SiC MOSFET, and the shielded gate electrode isolated from the epitaxial layer by an insulating film, wherein the first gate oxide has a thickness less than that of the insulating film. A second gate electrode laterally isolated from the epitaxial layer by a second gate oxide of the SiC SBR, wherein the second gate oxide has a thickness less than that of the first gate oxide; and the second gate electrode shorted to a source metal through a gate contact of the SiC SBR.

According to another aspect, the invention features a SiC power device further comprising: a shielded gate electrode disposed in a middle of the first type gate trench, and a pair of split gate electrodes as a first gate electrodes disposed surrounding an upper portion of the shielded gate electrode; the first gate electrodes laterally isolated from the epitaxial layer by a first gate oxide of the SiC MOSFET, and the shielded gate electrode isolated from the epitaxial layer by an insulating film; a second gate electrode laterally isolated from the epitaxial layer by a second gate oxide of the SiC SBR, wherein the second gate oxide has a thickness less than that of the first gate oxide; and the second gate electrode shorted to a source metal through a gate contact of the SiC SBR.

According to another aspect, the invention features a SiC power device further comprising a super junction (SJ) structure comprising a P column (PC) region of a second conductivity type. At least two sidewall P-shield (SPS) regions of a second conductivity type facing each other with a doping concentration higher than that of the PC region, adjoining the PC region, and a Junction Field Effect Transistor (JFET) region of a first conductivity type formed between the two adjacent SPS regions with a doping concentration higher than that of the epitaxial layer.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1A is a cross-sectional view showing a preferred SiC power device embodiment comprising a SiC MOSFET and a SiC SBR integrated in each unit cell according to the present invention.

FIG. 1B is a cross-sectional view showing another preferred SiC power device embodiment comprising a SiC MOSFET and a SiC SBR integrated in each unit cell with a third p body region having a third n+ source region thereon according to the present invention.

FIG. 1C is a cross-sectional view showing another preferred SiC power device embodiment comprising a SiC MOSFET and a SiC SBR integrated in each unit cell wherein the first gate electrode is laterally isolated from the adjacent epitaxial layer by two different gate oxide layers (GOX1 and GOX2) according to the present invention.

FIG. 1D is a cross-sectional view showing another preferred SiC power device embodiment comprising a SiC MOSFET and a SiC SBR integrated in each unit cell with a L-Shape P-shield (LPS) region beneath the first type gate trench according to the present invention.

FIG. 1E is a cross-sectional view showing another preferred SiC power device embodiment comprising a SiC MOSFET and a SiC SBR integrated in each unit cell with an N type buffer source region below the first and second source regions according to the present invention.

FIG. 1F is a cross-sectional view showing another preferred SiC power device embodiment comprising a SiC MOSFET and a SiC SBR integrated in each unit cell with saturation current pitching off (psc) regions according to the present invention.

FIG. 1G is a cross-sectional view showing another preferred SiC power device embodiment comprising a SiC MOSFET and a SiC SBR integrated in each unit cell with planar contacts according to the present invention.

FIG. 2A is a cross-sectional view showing another preferred SiC power device embodiment comprising a SiC MOSFET and a SiC SBR integrated in each unit cell with L-shape second p body and source regions according to the present invention.

FIG. 2B is a cross-sectional view showing another preferred SiC power device embodiment comprising a SiC MOSFET and a SiC SBR integrated in each unit cell with a LPS region beneath the first type gate trench according to the present invention.

FIG. 3A is a cross-sectional view showing another preferred SiC power device embodiment comprising a SiC MOSFET and a SiC SBR integrated in each unit cell with P column (PC) regions adjoining bottom surfaces of the p1 and p2 regions above the N+ substrate according to the present invention.

FIG. 3B is a cross-sectional view showing another preferred SiC power device embodiment comprising a SiC MOSFET and a SiC SBR integrated in each unit cell with an additional N buffer layer sandwiched between the N+ substrate and the PC regions according to the present invention.

FIG. 3C is a cross-sectional view showing another preferred SiC power device embodiment comprising a SiC MOSFET and a SiC SBR integrated in each unit cell with a Junction Field Effect Transistor (JFET) region formed between the two adjacent SPS regions according to the present invention.

FIG. 4A is a cross-sectional view showing another preferred SiC power device embodiment representing an IGBT with a P+ substrate according to the present invention.

FIG. 4B is a cross-sectional view showing another preferred SiC power device embodiment representing an IGBT with a plurality of alternating P+ and N+ regions in the P+ substrate according to the present invention.

FIG. 5A is a cross-sectional view showing another preferred SiC power device embodiment comprising a SiC MOSFET and a SiC SBR integrated in each unit cell with a shielded gate electrode disposed below a gate electrode in the first type gate trench according to the present invention.

FIG. 5B is a cross-sectional view showing another preferred SiC power device embodiment comprising a SiC MOSFET and a SiC SBR integrated in each unit cell with a LPS region beneath the first type gate trench according to the present invention.

FIG. 5C is a cross-sectional view showing another preferred SiC power device embodiment comprising a SiC MOSFET and a SiC SBR integrated in each unit cell according to the present invention, wherein the doping concentration variations of the N type epitaxial layer as grown are depicted along the vertical direction.

FIG. 5D is a cross-sectional view showing another preferred SiC power device embodiment comprising a SiC MOSFET and a SiC SBR integrated in each unit cell according to the present invention, wherein the doping concentration variations of the N type epitaxial layer as grown are depicted along the vertical direction.

FIG. 6A is a cross-sectional view showing another preferred SiC power device embodiment comprising a SiC MOSFET and a SiC SBR integrated in each unit cell with a pair of split gate electrodes surrounding an upper portion of the shielded gate electrode in the first type gate trench according to the present invention.

FIG. 6B is a cross-sectional view showing another preferred SiC power device embodiment comprising a SiC MOSFET and a SiC SBR integrated in each unit cell with a LPS region beneath the first type gate trench according to the present invention.

FIG. 6C is a cross-sectional view showing another preferred SiC power device embodiment comprising a SiC MOSFET and a SiC SBR integrated in each unit cell according to the present invention, wherein the doping concentration variations of the N type epitaxial layer as grown are depicted along the vertical direction.

FIG. 6D is a cross-sectional view showing another preferred SiC power device embodiment comprising a SiC MOSFET and a SiC SBR integrated in each unit cell according to the present invention, wherein the doping concentration variations of the N type epitaxial layer as grown are depicted along the vertical direction.

FIG. 7A is a cross-sectional view showing another preferred SiC power device embodiment comprising a SiC MOSFET and a SiC SBR integrated in each unit cell according to the present invention, wherein the SiC MOSFET has a one-step gate trench structure.

FIG. 7B is a cross-sectional view showing another preferred SiC power device embodiment comprising a SiC MOSFET and a SiC SBR integrated in each unit cell according to the present invention, wherein the SiC MOSFET has a one-step gate trench structure with a step P type shield (S-PS) region surrounding the bottom step trench.

FIG. 8 is a cross-sectional view showing another preferred SiC power device embodiment comprising a SiC MOSFET and a SiC SBR integrated in each unit cell according to the present invention, wherein the SiC MOSFET has a two-step gate oxide structure.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

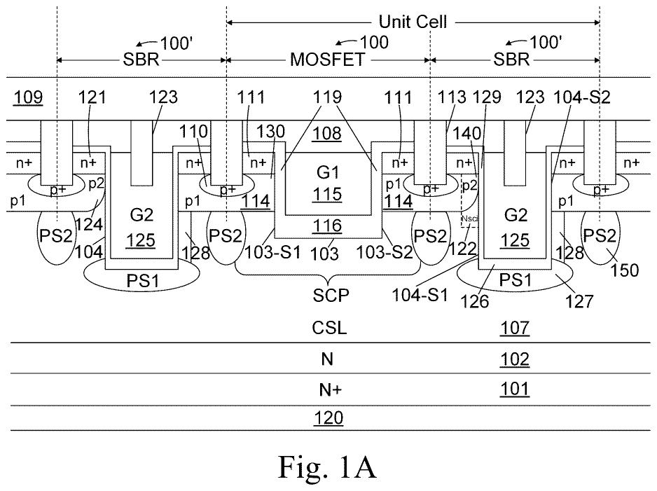

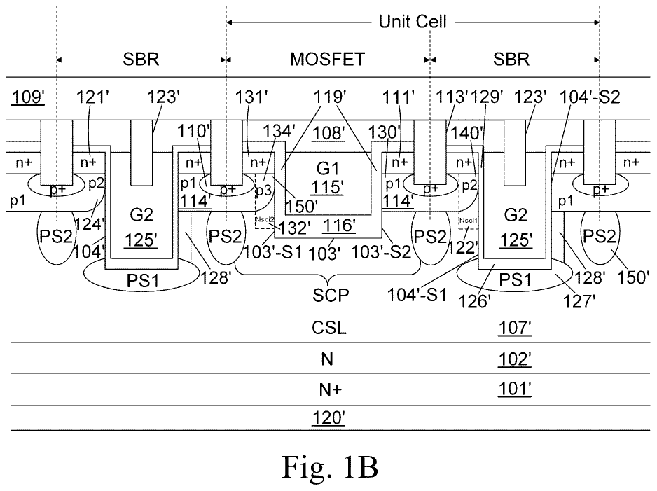

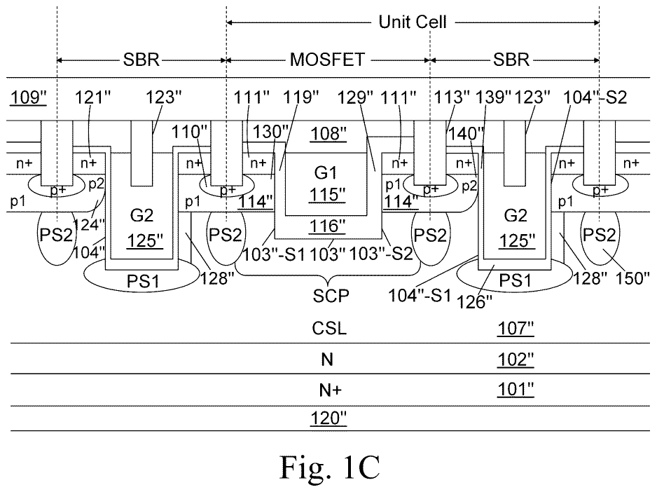

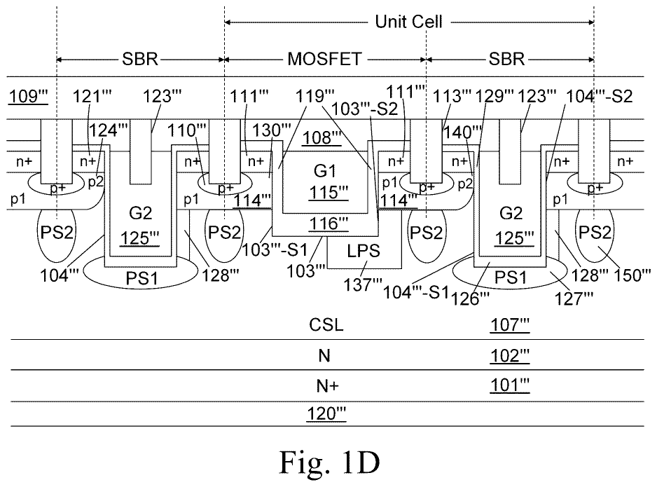

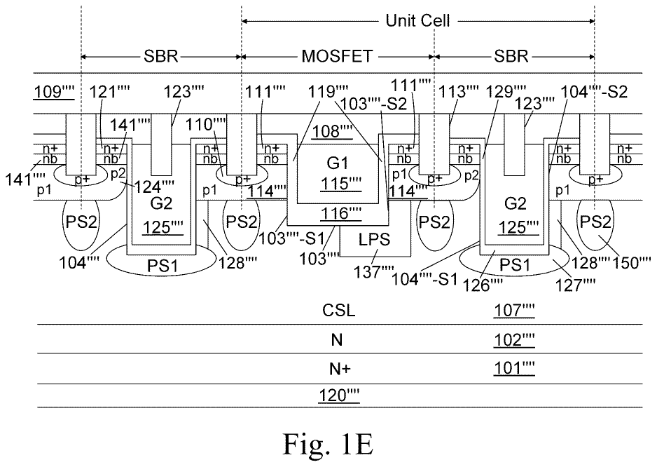

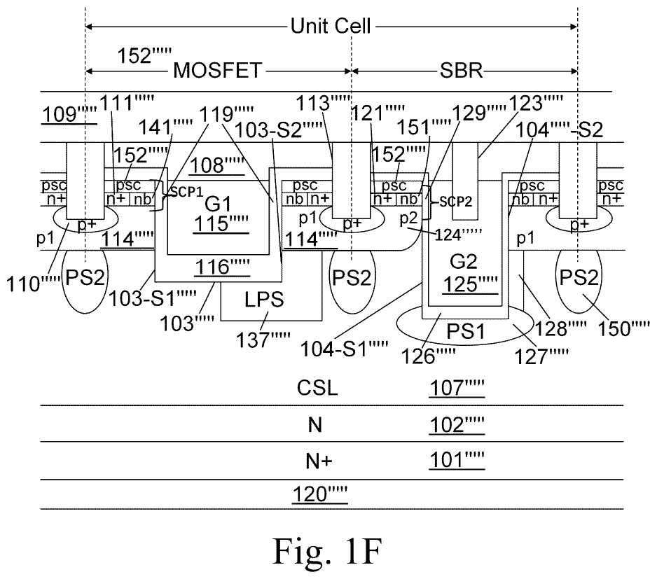

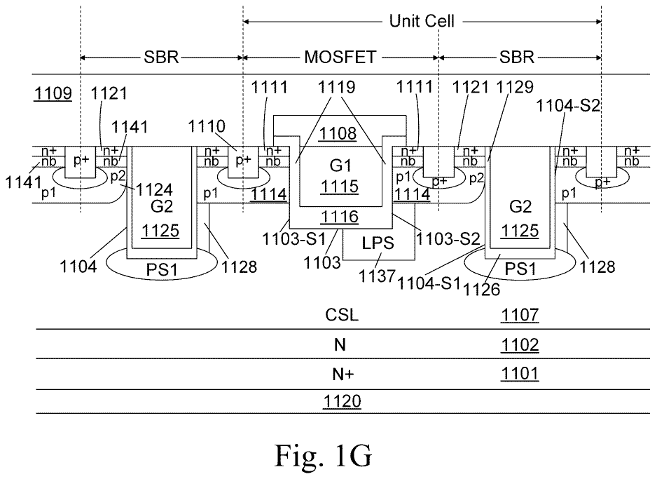

Please refer to FIG. 1A for a preferred embodiment of a SiC power device wherein an N-channel SiC MOSFET 100 and a SiC SBR 100′ are integrated in each unit cell which is formed on an N+ substrate 101 of a first type conductivity with a less doped N type epitaxial layer 102 extending thereon, wherein the N+ substrate 101 is coated with a back metal 120 on rear side as a drain metal. Each unit cell comprises a first type gate trench 103 and a second type gate trench 104 formed vertically downward from a top surface of the N type epitaxial layer 102 and not reaching the common interface between the N type epitaxial layer 102 and the N+ substrate 101, wherein the second type gate trench 104 has a trench depth deeper than that of the first type gate trench 103. Inside each of the first type gate trenches 103, a first gate electrode (G1, as illustrated) 115 of the SiC MOSFET 100 is disposed in an upper portion and laterally isolated from the adjacent epitaxial layer by a first gate oxide (GOX1) 119 of the SiC MOSFET 100, and vertically isolated from the adjacent epitaxial layer by a first insulating film 116 on a bottom region of the gate trench 103 with a thickness greater than that of the first gate oxide 119. While a second gate electrode (G2, as illustrated) 125 of the SiC SBR 100′ is formed inside each of the second type gate trenches 104, and laterally isolated from the adjacent epitaxial layer by a second gate oxide (GOX2) 129 of the SiC SBR 100′ with a thickness thinner than the GOX1 119 and vertically isolated from the adjacent epitaxial layer by a second insulating film 126 on a bottom region of the gate trench 104 with a thickness greater than that of the GOX2 129 and thinner than that of the first insulating film 116. In the MOSFET 100, a p1 body region 114 of a second conductivity type having a first n+ source region 111 thereon is extending in an upper portion of the N type epitaxial layer 102 and surrounding the first gate electrodes 115 padded by the first gate oxide film 119, wherein a first gate channel region 130 is formed between the p1 body region 114 and the first source region 111 along the gate sidewalls; while in the SBR 100′, a p2 body region 124 having a second n+ source region 121 thereon is extending in an upper portion of the N type epitaxial layer 102 and surrounding the second gate electrodes 125 padded by the second gate oxide film 129, wherein a second gate channel region 140 is formed between the p2 body region 124 and the second source region 121 along a first gate sidewall 104-S1 of the second type gate trench 104 with a channel length shorter than that of the first gate channel region 130, and an N type short channel implant (Nsci, as illustrated) region 122 is formed into the second gate channel region 140 along upper sidewalls of the second type gate trench 104. Moreover, N type current spreading layer (CSL, as illustrated) region 107 is formed at a top portion of the epitaxial layer 102 by ion implantation or epitaxial layer growth methods with a doping concentration higher than that of the N type epitaxial layer 102, and a first P-shield (PS1, as illustrated) region 127 of a second conductivity type for the gate oxide electric-field reduction is formed surrounding a bottom region of the second type gate trench 104 and being spaced apart from the first type gate trenches 103, and a sidewall P type region 128 of a second conductivity type is formed along a second sidewall 104-S2 of the second type gate trench 104, connecting the PS1 region 127 to the p1 body region 114. An interlayer dielectric film 108 is stacked on the epitaxial layer 102, and a source metal 109 is formed onto the interlayer dielectric film 108. The p1 and p2 body regions 114 and 124, and the first and second n+ source regions 111 and 121 are shorted to the source metal 109 through a plurality of trenched source contacts 113 filled with contact metal plugs and metal barriers and surrounded by p+ heavily doped regions 110 around bottoms underneath the first and second n+ source regions 111 and 121, and the G2 125 of the SiC SBR 100′ is shorted to the source metal 109 through the trenched gate contact 123. The present structure further comprises a second P-shield (PS2, as illustrated) region 150 of a second conductivity type for the gate oxide electric field reduction, adjoining a lower surface of the p1 body regions 114 and being spaced apart from the first type gate trenches 103 and the second type gate trenches 104. According to this invention, a saturation current pitching (SCP, as illustrated) region is formed between the two adjacent PS2 regions 150 as well for the short circuit capability enhancement.

Please refer to FIG. 1B for another preferred embodiment of a SiC power device with a new and improved device structure. The SiC power device has a similar structure to FIG. 1A, except that the present invention further comprises a third p body (p3, as illustrated) region 134′ having a third n+ source region 131′ thereon in an upper portion of the N type epitaxial layer 102′ and surrounding the first gate electrodes 115′ padded by the first gate oxide film (GOX1) 119′ with a doping concentration lower than that of the first body (p1, as illustrated) region 114′. A third gate channel region 150′ of the SiC MOSFET is formed in the p3 region 134′ along a first sidewall 103′-S1 of the first type gate trench 103′, and a first gate channel region 130′ of the SiC MOSFET is formed along a second sidewall 103′-S2 of the first type gate trench 103′ opposite to the first sidewall of the first type gate trench 103′. Moreover, a second short channel implant (Nsci2, as illustrated) region 132′ of a first conductivity type is formed into the third gate channel region 150′.

Please refer to FIG. 1C for another preferred embodiment of a SiC power device with a new and improved device structure. The SiC power device has a similar structure to FIG. 1A, except that the first gate electrode (G1, as illustrated) 115″ of the SiC MOSFET in the present invention is laterally isolated from the epitaxial layer 102″ by a first gate oxide (GOX1) 119″ of the SiC MOSFET on a first sidewall 103″-S1 facing the sidewall P type region 128″, and by a second gate oxide (GOX2) 129″ of the SiC MOSFET on a second sidewall 103″-S2 opposite to the first sidewall 103″-S1 of the first type gate trench 103″, and the second gate electrode (G2, as illustrated) 125″ is laterally isolated from the epitaxial layer by a third gate oxide (GOX3) 139″ of the SiC SBR, wherein the GOX2 129″ has a thickness larger than that of the GOX1 119″, and the GOX1 119″ has a thickness larger than that of the GOX3 139″.

Please refer to FIG. 1D for another preferred embodiment of a SiC power device with a new and improved device structure. The SiC power device has a similar structure to FIG. 1A, except that the present invention further comprises a L-Shape P-shield (LPS, as illustrated) region 137′″ of a second conductivity type beneath the first type gate trench 103′″ and aside a second sidewall 103′″-S2 of the first type gate trench 103′″ directly facing to the first gate sidewall 104′″-S1 of the second type gate trench 104′″ and adjoining a lower surface of the first body (p1, as illustrated) region 114′″.

Please refer to FIG. 1E for another preferred embodiment of a SiC power device with a new and improved device structure. The SiC power device has a similar structure to FIG. 1D, except that the present invention further comprises an N type buffer source (nb, as illustrated) region 141″″ below the first and second source regions 111″″ and 121″″ with a doping concentration lower than that of the first and second source regions 111″″ and 121″″ for the short circuit capability enhancement.

Please refer to FIG. 1F for another preferred embodiment of a SiC power device with a new and improved device structure. The SiC power device has a similar structure to FIG. 1D, except that the present invention further comprises a first N type buffer source region 141″″ formed in a side of the first source region 111′″″ adjacent to the first gate channel region 130′″″ with a doping concentration lower that of the first source region 111′″″ and a second N type buffer source region 151′″″ formed in a side of the second source region 121′″″ adjacent to the second gate channel region 140′″″ with a doping concentration lower that of the first source region 111′″″, and furthermore, a heavily doped P type region (psc, as illustrated) 152′″″ for formation of a first and a second saturation current pitching (SCP1 and SCP2 regions, as illustrated) is disposed on a top of the first and second source regions 111′″″ and 121′″″ and the first and second buffer source regions 141′″″ and 151″″″, and is shorted to the source metal 109′″″ through trenched source contacts 113′″″, wherein the SCP1 region is formed between the psc region 152′″″ and the first body region 114′″″ while the SCP2 region formed between the psc region 152′″″ and the second body region 124′″″.

Please refer to FIG. 1G for another preferred embodiment of a SiC power device with a new and improved device structure. The SiC power device has a similar structure to FIG. 1E, except that the source contacts in the present invention are planar contacts.

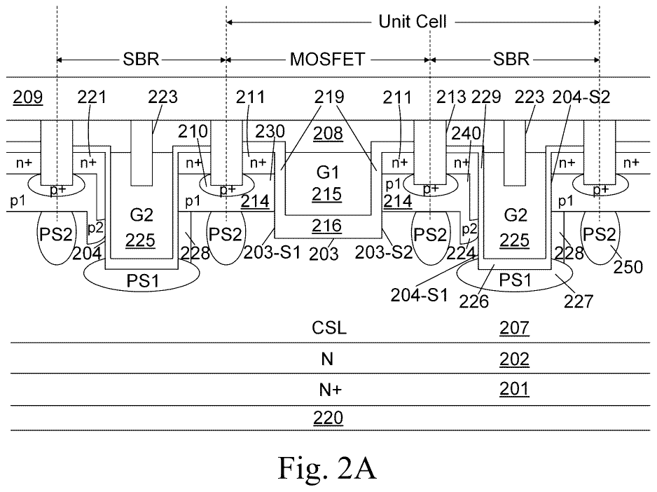

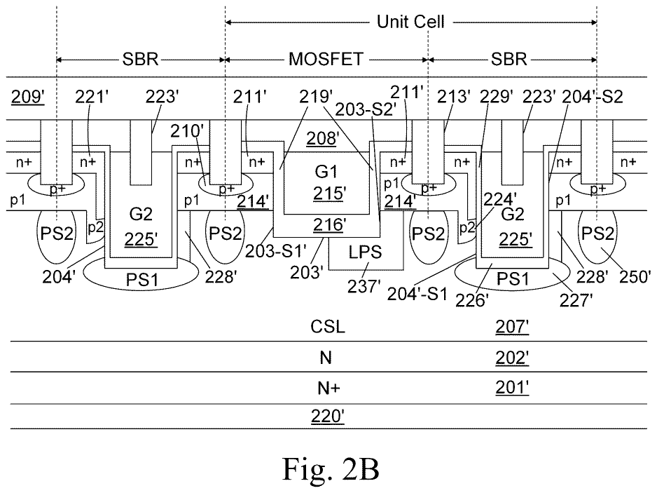

Please refer to FIG. 2A for another preferred embodiment of a SiC power device with a new and improved device structure. The SiC power device has a similar structure to FIG. 1A, except that the second source and second body regions 221 and 224 in the present invention have a L-shape structure and extend from a top portion of the epitaxial layer 202 toward the PS1 region 227 along a first sidewall 204-S1 of the second type gate trench 204 to an optimized position spaced apart from the PS1 region.

Please refer to FIG. 2B for another preferred embodiment of a SiC power device with a new and improved device structure. The SiC power device has a similar structure to FIG. 1D, except that the second source and second body regions 221′ and 224′ in the present invention have a L-shape structure and extend from a top portion of the epitaxial layer 202′ toward the PS1 region 227′ along a first sidewall 204′-S1 of the second type gate trench 204′.

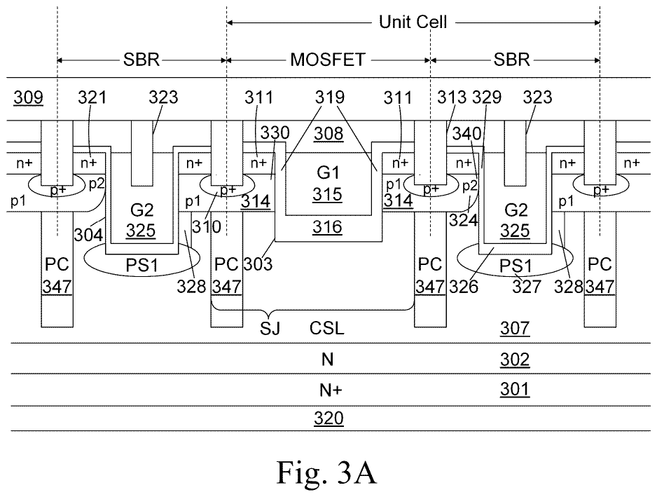

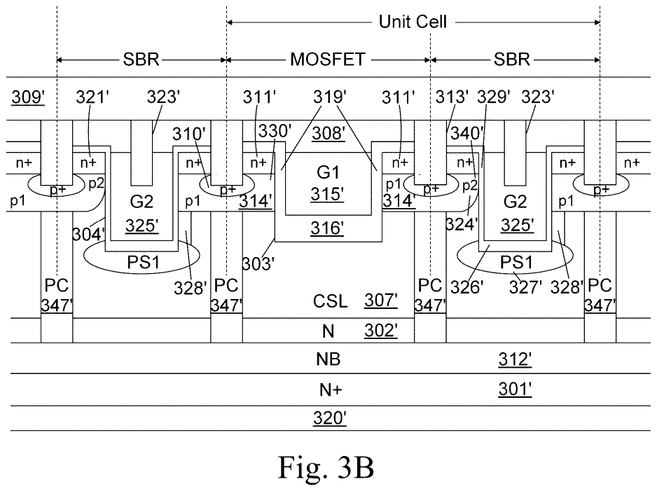

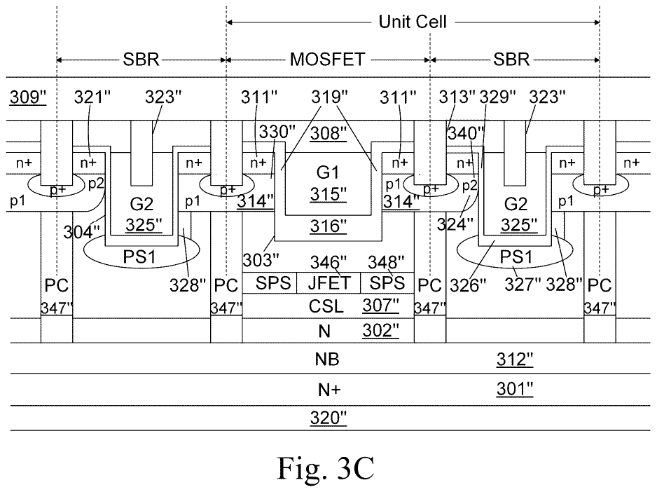

Please refer to FIG. 3A for another preferred embodiment of a SiC power device with a new and improved device structure. The SiC power device has a similar structure to FIG. 1A, except that the present invention further comprises P column (PC, as illustrated) regions 347 of a second conductivity type formed adjoining bottom surfaces of the p1 and p2 regions 314 and 324 above the N+ substrate 301, wherein the PC regions 347 may be formed by a channeling implantation through the trenched source contacts 313 or by a multiple-epitaxial layer growth method with a depth deeper than that of the second type gate trench 304. A super junction (SJ, as illustrated) structure is thus generated by the PC region 347 and the CSL region 307.

Please refer to FIG. 3B for another preferred embodiment of a SiC power device with a new and improved device structure. The SiC power device has a similar structure to FIG. 3A, except that the present invention further comprises an additional N buffer layer (NB, as illustrated) 312′ with a resistivity Rb sandwiched between the N+ substrate 301′ and the PC regions 347′, wherein Rb is higher than a resistivity R of the N type epitaxial layer 302′.

Please refer to FIG. 3C for another preferred embodiment of a SiC power device with a new and improved device structure. The SiC power device has a similar structure to FIG. 3B, except that the present invention further comprises two sidewall P-shield (SPS, as illustrated) regions 348″ of a second conductivity type facing each other horizontally adjoining the P column (PC, as illustrated) regions 347″ and being spaced apart from the first body regions 314″ with a doping concentration higher than that of the PC regions 347″, and a Junction Field Effect Transistor (JFET, as illustrated) region 346″ of a first conductivity type is formed between the two SPS regions 348″ with a doping concentration higher than that of the N type epitaxial layer 302″.

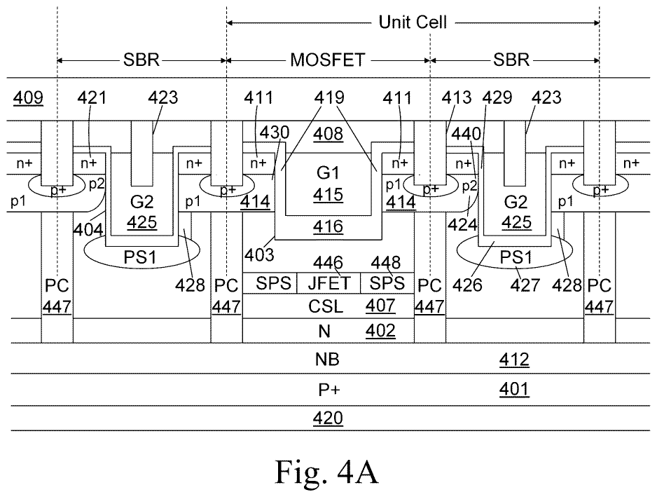

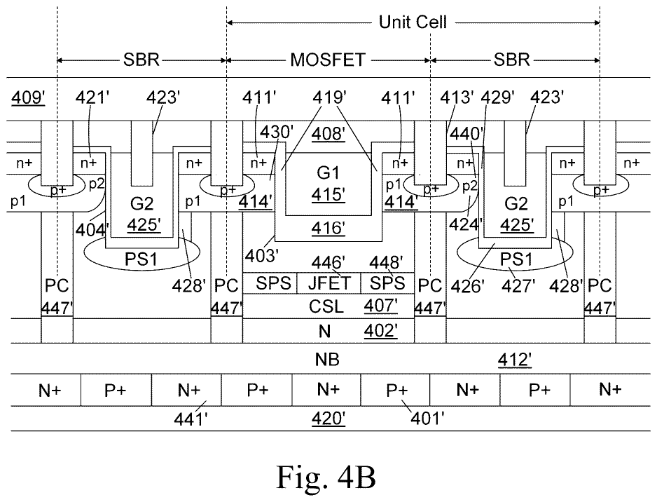

Please refer to FIG. 4A for another preferred embodiment of a SiC power device with a new and improved device structure. The SiC power device has a similar structure to FIG. 3C, except for the different substrate. In this invention, the SiC power device is formed on a P+ substrate 401, and the N buffer layer (NB, as illustrated) 412 sandwiched between the P+ substrate 401 and the PC regions 447 has a resistivity Rb lower than a resistivity R of the N type epitaxial layer 402.

Please refer to FIG. 4B for another preferred embodiment of a SiC power device with a new and improved device structure. The SiC power device has a similar structure to FIG. 4A, except that, the SiC power device in FIG. 4B further comprises a plurality of heavily doped N+ regions 441′ in the P+ substrate 401′ to form a plurality of alternating P+ and N+ regions in the substrate.

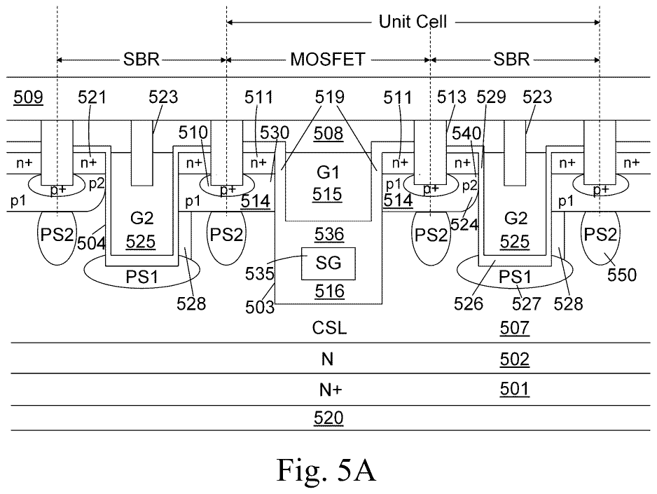

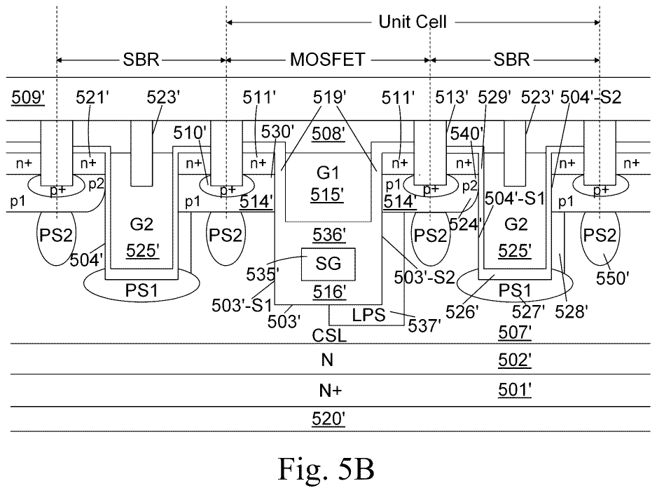

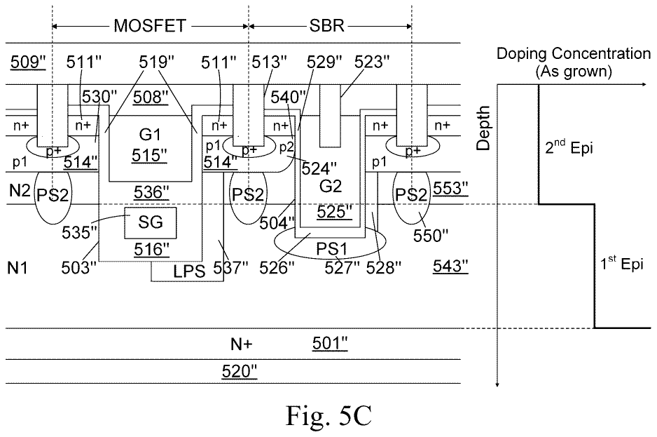

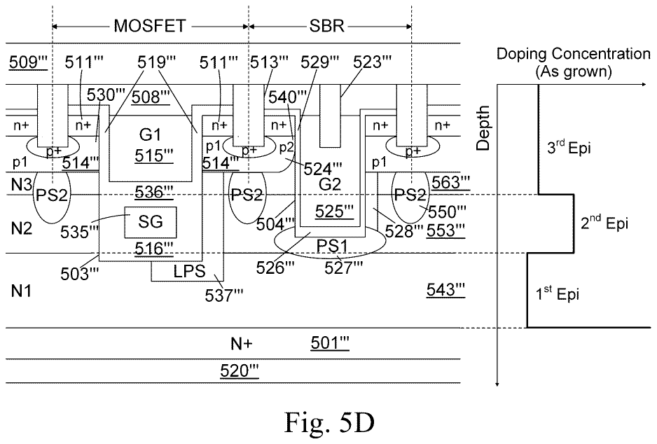

Please refer to FIG. 5A for another preferred embodiment of a SiC power device with a new and improved device structure. The SiC power device has a similar structure to FIG. 1A, except for the different shielded gate structure in the first type gate trenches 503. In the present structure, inside each of the first type gate trenches 503, a shielded gate electrode (SG, as illustrated) 535 is disposed in a lower portion of the gate trench below a first gate electrode (G1, as illustrated) 515 in an upper portion, and the first gate electrode 515 is laterally isolated from the adjacent epitaxial layer with a first gate oxide (GOX1) 519 on the gate sidewall, the shielded gate electrode 535 is isolated from the adjacent epitaxial layer by an insulating layer 516, wherein the insulating layer 516 has a thicker thickness than the first gate oxide 519. Meanwhile, the shielded gate electrode 535 and the first gate electrode 515 is insulated from each other by another insulating film 536 as an inter-poly oxide (IPO) layer.

Please refer to FIG. 5B for another preferred embodiment of a SiC power device with a new and improved device structure. The SiC power device has a similar structure to FIG. 5A, except that the present invention further comprises a L-Shape P-shield (LPS, as illustrated) region 537′ of a second conductivity type beneath the first type gate trench 503′ and aside a second sidewall 503′-S2 of the first type gate trench 503′ directly facing to the first gate sidewall 504′-S1 of the second type gate trench 504′ and adjoining a lower surface of the first body (p1, as illustrated) region 514′.

Please refer to FIG. 5C for another preferred embodiment of a SiC power device with a new and improved device structure, wherein the doping concentration variations of the N type epitaxial layer as grown are depicted along the vertical direction. The SiC power device has a similar structure to FIG. 5B, except for the different epitaxial layers. In this invention, the N type epitaxial layer comprises two stepped epitaxial layers of different doping concentrations including a bottom 1^{st} epitaxial layer (N1, as illustrated) 543″ with a doping concentration D1 and a top 2^{nd} epitaxial layer (N2, as illustrated) 553″ above the bottom 1^{st} epitaxial layer 543″ with a doping concentration D2, wherein D2<D1, to increase the breakdown voltage and reduce the specific on-resistance.

Please refer to FIG. 5D for another preferred embodiment of a SiC power device with a new and improved device structure, wherein the doping concentration variations of the N type epitaxial layer as grown are depicted along the vertical direction. The SiC power device has a similar structure to FIG. 5B, except for the different epitaxial layers. In this invention, the N type epitaxial layer comprises three stepped epitaxial layers of different doping concentrations including a bottom 1^{st} epitaxial layer (N1, as illustrated) 543′″ with a doping concentration D1, a middle 2^{nd} epitaxial layer (N2, as illustrated) 553′″ above the bottom 1^{st} epitaxial layer 543′″ with a doping concentration D2, and a top 3^{rd} epitaxial layer (N3, as illustrated) 563′″ above the middle 2^{nd} epitaxial layer 553′″ with a doping concentration D3, wherein D1<D3<D2, to increase the breakdown voltage and reduce the specific on-resistance.

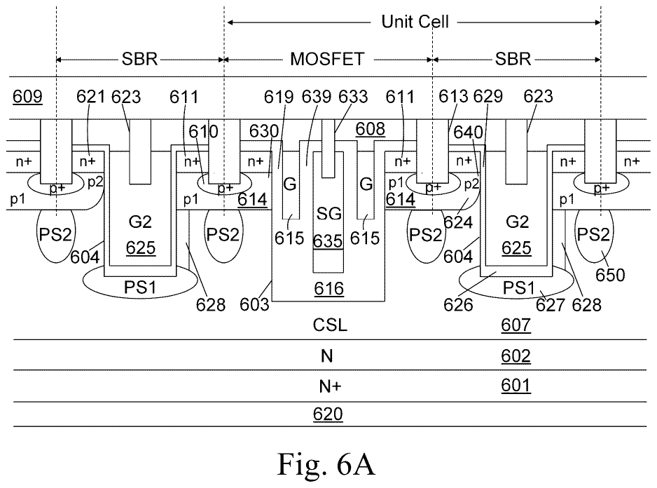

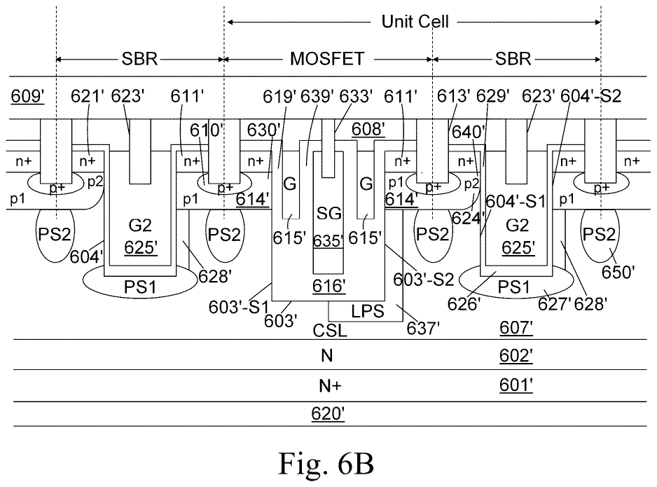

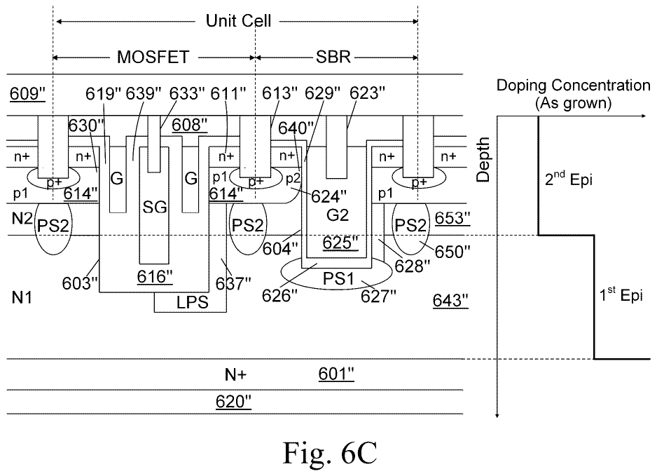

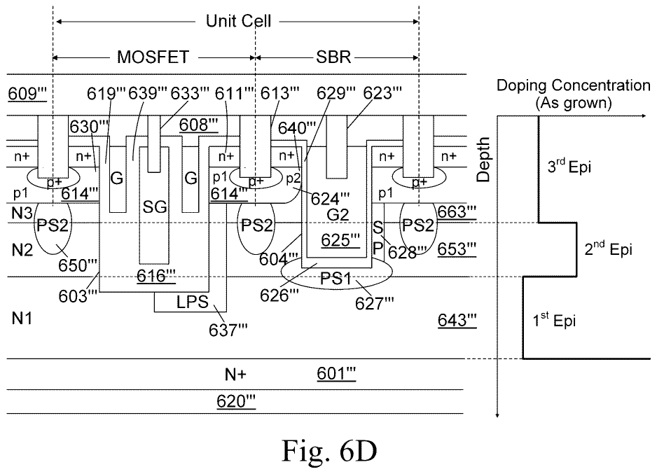

Please refer to FIG. 6A for another preferred embodiment of a SiC power device with a new and improved device structure. The SiC power device has a similar structure to FIG. 1A, except for the different shielded gate structure in the first type gate trenches 603. In the present structure, inside each of the first type gate trenches 603, a shielded gate electrode (SG, as illustrated) 635 is disposed in the middle and a pair of split gate electrodes (G, as illustrated) 615 are disposed surrounding an upper portion of the shielded gate electrode 635 as the first gate electrodes. The first gate electrodes 615 are laterally isolated from the epitaxial layer with a first gate oxide (GOX1) 619 of the SiC MOSFET on the gate sidewall, and the shielded gate electrode 635 is vertically isolated from the epitaxial layer with an insulating film 616 on a bottom of the first type gate trench 603. Moreover, another insulating film 639 isolating the shielded gate electrode 635 from the first gate electrodes 615 is covering on an upper portion of the shielded gate electrode 635, wherein the insulating film 639 is formed at the same time during growing the gate oxide 619 in the manufacturing process. Furthermore, the shielded gate electrode 635 is connected to a source metal 609 through a trenched contact 633.

Please refer to FIG. 6B for another preferred embodiment of a SiC power device with a new and improved device structure. The SiC power device has a similar structure to FIG. 6A, except that the present invention further comprises a L-Shape P-shield (LPS, as illustrated) region 637′ of a second conductivity type beneath the first type gate trench 603′ and aside a second sidewall 603′-S2 of the first type gate trench 603′ directly facing to the first gate sidewall 604′-S1 of the second type gate trench 604′ and adjoining a lower surface of the first body (p1, as illustrated) region 614′.

Please refer to FIG. 6C for another preferred embodiment of a SiC power device with a new and improved device structure, wherein the doping concentration variations of the N type epitaxial layer as grown are depicted along the vertical direction. The SiC power device has a similar structure to FIG. 6B, except for the different epitaxial layers. In this invention, the N type epitaxial layer comprises two stepped epitaxial layers of different doping concentrations including a bottom 1^{st} epitaxial layer (N1, as illustrated) 643″ with a doping concentration D1 and a top 2^{nd} epitaxial layer (N2, as illustrated) 653″ above the bottom 1^{st} epitaxial layer 643″ with a doping concentration D2, wherein D2<D1, to increase the breakdown voltage and reduce the specific on-resistance.

Please refer to FIG. 6D for another preferred embodiment of a SiC power device with a new and improved device structure, wherein the doping concentration variations of the N type epitaxial layer as grown are depicted along the vertical direction. The SiC power device has a similar structure to FIG. 6B, except for the different epitaxial layers. In this invention, the N type epitaxial layer comprises three stepped epitaxial layers of different doping concentrations including a bottom 1^{st} epitaxial layer (N1, as illustrated) 643′″ with a doping concentration D1, a middle 2^{nd} epitaxial layer (N2, as illustrated) 653′″ above the bottom 1^{st} epitaxial layer 643′″ with a doping concentration D2, and a top 3^{rd} epitaxial layer (N3, as illustrated) 663′″ above the middle 2^{nd} epitaxial layer 653′″ with a doping concentration D3, wherein D1<D3<D2, to increase the breakdown voltage and reduce the specific on-resistance

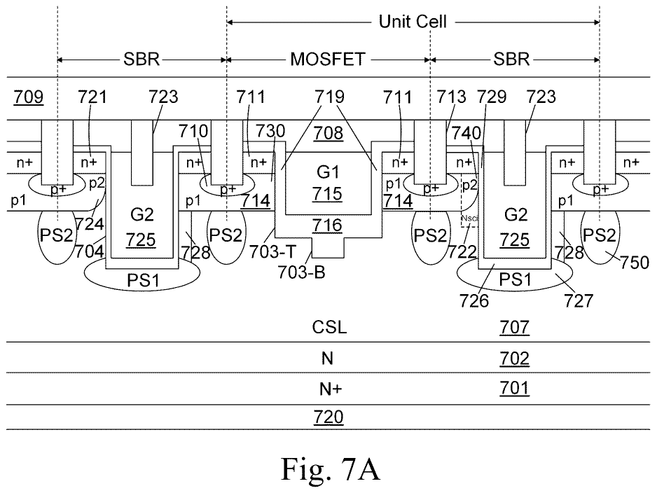

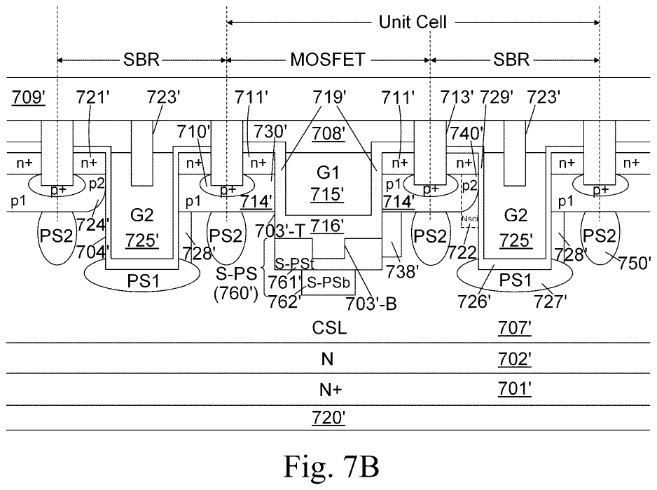

Please refer to FIG. 7A for another preferred embodiment of a SiC power device with a new and improved device structure. The SiC power device has a similar structure to FIG. 1A, except that the first type gate trench 703 of the SiC MOSFET in the present invention has a one-step gate trench structure comprising a top gate trench 703-T and a bottom gate trench 704-B, wherein the top gate trench 703-T is above the bottom gate trench 703-B with a gate width greater than that of the bottom gate trench 703-B. A first gate electrode (G1, as illustrated) 715 is disposed in the top gate trench 703-T surrounded with a thick bottom oxide as the first insulating film 716 on a bottom region of the top gate trench 703-T, and surrounded with a first gate oxide (GOX1) 719 on sidewalls of the top gate trench 703-T, wherein the GOX1 719 has a less thickness than the first insulating film 716. Moreover, the bottom gate trench 703-B is filled up with the first insulating film 716.

Please refer to FIG. 7B for another preferred embodiment of a SiC power device with a new and improved device structure. The SiC power device has a similar structure to FIG. 7A, except that the present invention further comprises a step P-shield region (S-PS) 760′ of a second conductivity type for the gate oxide electric-field reduction surrounding the bottom gate trench 703′-B filled up with the first insulating film 716′. The S-PS region 760′ comprises two sub-S-PS regions including a top S-PS (S-PSt, as illustrated) region 761′ and a bottom S-PS (S-PSb, as illustrated) region 762′, wherein the S-PSb region 762′ is below the S-PSt region 761′ with a doping concentration lower than that of the S-PSt region 761′. Moreover, a second sidewall P type region 738′ is formed along a second sidewall of the first type gate trench, connecting the S-PS region 760′ to the first body (p1, as illustrated) region 714′.

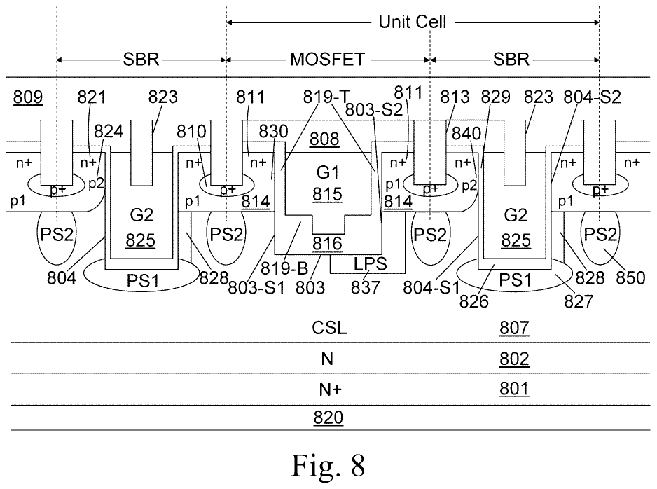

Please refer to FIG. 8 for another preferred embodiment of a SiC power device with a new and improved device structure. The SiC power device has a similar structure to FIG. 1D, except that the first type gate trench 803 of the SiC MOSFET in the present invention has a two-step gate oxide structure therein comprising a first top gate oxide(GOX1-T) 819-T and a first bottom gate oxide (GOX1-B) 819-B, wherein the first top gate oxide 819-T is above the first bottom gate oxide 819-B with a gate oxide thickness less than that of the first bottom gate trench 819-B. A first gate electrode (G1, as illustrated) 815 is disposed in the first type gate trench 803 surrounded with a thick bottom oxide as the first insulating film 816 on a bottom region of the first type gate trench 803, and surrounded with a first top gate oxide 819-T on upper portion of sidewalls of the first type gate trench 803 and surrounded with a first bottom gate oxide 819-B on lower portion of sidewalls of the first type gate trench 803, wherein the GOX 819-T has a less thickness than the first insulating film 816. A first gate channel region 830 of said first SiC MOSFET formed in said first body region 814 along a first sidewall 803-S1 of said first type gate trench connecting to said first source region 811; and a L-shape P-shield (LPS) region of said second conductivity type disposed beneath said first type gate trench, and aside a second sidewall 803-S2 of said first type gate trench 803 and adjoining a lower surface of said first body region 814. A second P-shield (PS2) region of said second conductivity type adjoining a lower surface of said first body region for the gate oxide electric field and saturation current reductions.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A SiC power device comprising a SiC MOSFET and a SiC super barrier rectifier (SBR) disposed in each unit cell having two type gate trenches comprising:
an epitaxial layer of a first conductivity type grown on a substrate;
said SiC MOSFET further comprising:
a first type gate trench;
a first body region of a second conductivity type having a first source region of said first conductivity type thereon;
a first gate channel region of said SiC MOSFET formed in said first body region along at least one sidewall of said first type gate trench connecting to said first source region;
said SiC SBR further comprising:
a second type gate trench;
a second body region of said second conductivity type having a second source region of said first conductivity type thereon;
a second gate channel region of said SiC SBR formed in said second body region along a first sidewall of said second type gate trench connecting to said second source region;
a first P-shield (PS1) region of said second conductivity type surrounding a bottom region of said second type gate trench and being spaced apart from said first type gate trench;
a first sidewall P type region of said second conductivity type formed along a second sidewall of said second type gate trench opposite to said first sidewall of said second type gate trench, connecting said PS1 region to said first body region;
said second body region has a doping concentration lower than that of said first body region;
a first gate electrode of said SiC MOSFET disposed in said first type gate trench and a second gate electrode of said SiC SBR disposed in said second type gate trench; and
said first and second body regions, said first and second source regions and said second gate electrode being shorted to a source metal through source contacts.

2. The SiC power device of claim 1, said SiC power device further comprising a second P-shield (PS2) region of said second conductivity type adjoining a lower surface of said first body region for the gate oxide electric field and saturation current reductions.

3. The SiC power device of claim 1, further comprising a current spreading layer (CSL) region of said first conductivity type formed at a top portion of said epitaxial layer with a doping concentration higher than that of said epitaxial layer.

4. The SiC power device of claim 1, further comprising:
a third gate channel region of said SiC MOSFET formed in a third body region along a first sidewall of said first type gate trench, and said first gate channel region of said SiC MOSFET formed along a second sidewall of said first type gate trench opposite to said first sidewall of said first type gate trench; and
said third body region has a doping concentration lower than that of said first body region.

5. The SiC power device of claim 1, wherein said first gate electrode surrounded with a first insulating film on a bottom region of said first type gate trench, and with a first gate oxide on a first sidewall and with a second gate oxide on a second sidewall opposite to said first sidewall of said first type gate trench; said first insulating film has a greater thickness than said first and second gate oxides; and
said second gate electrode surrounded with a second insulating film on a bottom region of said second type gate trench, and surrounded with a third gate oxide on sidewalls of said second type gate trench; and said third gate oxide has a thinner thickness than said second insulating film and said first and second gate oxides.

6. The SiC power device of claim 1, further comprising a L-shape P-shield (LPS) region of said second conductivity type beneath said first type gate trench, and aside a sidewall of said first type gate trench and adjoining a lower surface of said first body region.

7. The SiC power device of claim 1, further comprising a first short channel implant (SCI) region of said first conductivity type formed into said second gate channel region.

8. The SiC power device of claim 4, further comprising a second SCI region of said first conductivity type formed into said third gate channel region.

9. The SiC power device of claim 1, further comprising a buffer source region of said first conductivity type below said first and second source regions with a doping concentration lower than that of said first and second source regions.

10. The SiC power device of claim 1, further comprising:
a first buffer source region of said first conductivity type formed in a side of said first source region adjacent to said first gate channel region with a doping concentration lower than that of said first source region;
a second buffer source region of said first conductivity type formed in a side of said second source region adjacent to said second gate channel region with a doping concentration lower than that of said first source region; and
a heavily doped P type region of said second conductivity type for the formation of a saturation current pitching region of said second conductivity type disposed on top of said first and second source regions, and said first and second buffer source regions, shorted to said source metal through said source contacts.

11. The SiC power device of claim 1, wherein said second source and second body regions extending from a top portion of said epitaxial layer toward said PS1 region along said first sidewall of said second type gate trench to an optimized position spaced apart from said PS1 region.

12. The SiC power device of claim 1, further comprising a super junction (SJ) structure comprising a P column (PC) region of said second conductivity type disposed on a buffer layer of said first conductivity type with a resistivity Rb sandwiched between said substrate and said epitaxial layer, and said PC region is connected to said first body region.

13. The SiC power device of claim 12, wherein said substrate has said first conductivity type and said epitaxial layer comprises a single epitaxial layer having a uniform doping concentration with a resistivity R, and said R<said Rb.

14. The SiC power device of claim 1, wherein said substrate comprising a plurality of heavily doped regions of said first conductivity type into said substrate to form a plurality of alternating P+ and N+ regions in said substrate; and said epitaxial layer comprises a single epitaxial layer having a uniform doping concentration with a resistivity R, and said R>said Rb.

15. The SiC power device of claim 13, further comprising at least two sidewall P-shield (SPS) regions of said second conductivity type facing each other with a doping concentration higher than that of said PC region, adjoining said PC region and being spaced apart from said first body region, and a Junction Field Effect Transistor (JFET) region of said first conductivity type formed between said two adjacent SPS regions with a doping concentration higher than that of said epitaxial layer.

16. The SiC power device of claim 1, wherein said first gate electrode is disposed in an upper portion of said first type gate trench, and a shielded gate electrode is disposed below said first gate electrode and isolated from each other by an inter-poly oxide (IPO) layer;
said first gate electrode is laterally isolated from said epitaxial layer by a first gate oxide of said SiC MOSFET, and said shielded gate electrode is isolated from said epitaxial layer by a first insulating film, wherein said first gate oxide has a thickness less than that of said first insulating film;
a first gate channel region of said first SiC MOSFET formed in said first body region along a first sidewall of said first type gate trench connecting to said first source region; and
a L-shape P-shield (LPS) region of said second conductivity type disposed beneath said first type gate trench, and aside a second sidewall of said first type gate trench and adjoining a lower surface of said first body region;
said second gate electrode is laterally isolated from said epitaxial layer by a second gate oxide of said SiC SBR, wherein said second gate oxide has a thickness less than that of said first gate oxide; and
said epitaxial layer comprises at least two sub-epitaxial layers of different doping concentrations including a bottom epitaxial layer with a doping concentration D1 and a top epitaxial layer above said bottom epitaxial layer with a doping concentration D2, wherein said D2<D1.

17. The SiC power device of claim 5, wherein said first type gate trench has a one-step gate trench structure comprising a top gate trench and a bottom gate trench; said top gate trench is disposed above said bottom gate trench with a trench width wider than that of said bottom gate trench; and said bottom gate trench is filled up with said first insulating film.

18. The SiC power device of claim 17, further comprising a step P-shield (S-PS) region of said second conductivity type surrounding said bottom gate trench filled up with said first insulating film; said S-PS region comprising two sub-S-PS regions including a top S-PS region and a bottom S-PS region, wherein said bottom S-PS region is disposed below said top S-PS region with a doping concentration lower than that of said top S-PS region; and a second sidewall P type region of said second conductivity type formed along a sidewall of said first type gate trench, connecting said S-PS region to said first body region.

19. A SiC power device comprising a SiC MOSFET comprising:
an epitaxial layer of a first conductivity type grown on a substrate;
said SiC MOSFET having a first type gate trench with at least two-step gate oxide structure formed therein;
said at least two-step gate oxide structure comprising a first top gate oxide and a first bottom gate oxide; said first top gate oxide is above said first bottom gate oxide along said first type gate trench and has a gate oxide thickness less than that of said first bottom gate oxide;
a first gate electrode disposed in said first type gate trench surrounded with a first insulating film on a bottom region of said first top gate trench, with said first top gate oxide on upper portion of sidewalls of said first type gate trench and with said first bottom gate oxide on lower portion of sidewalls of said first type gate trench; said first insulating film having a thickness greater than that of said first top gate oxide;
a first body region of a second conductivity type having a first source region of said first conductivity type thereon;
a first gate channel region of said first SiC MOSFET formed in said first body region along a first sidewall of said first type gate trench connecting to said first source region;
a current spreading layer (CSL) region of said first conductivity type formed at a top portion of said epitaxial layer with a doping concentration higher than that of said epitaxial layer.
a L-shape P-shield (LPS) region of said second conductivity type disposed beneath said first type gate trench, and aside a second sidewall of said first type gate trench and adjoining a lower surface of said first body region; and
a second P-shield (PS2) region of said second conductivity type adjoining a lower surface of said first body region for the gate oxide electric field and saturation current reductions.

20. A SiC power device of claim 19, further comprising:
a SiC SBR integrated with said SiC MOSFET in each unit cell:
a second type gate trench formed in said epitaxial layer for formation of a second gate channel region of SiC SBR;
a second body region of said second conductivity type having a second source region of said first conductivity type thereon;
said second gate channel region of said SiC SBR formed in said second body region along a first sidewall of said second type gate trench connecting to said second source region;
a first P-shield (PS1) region of said second conductivity type surrounding a bottom region of said second type gate trench and being spaced apart from said first type gate trench;
a first sidewall P type region of said second conductivity type formed along a second sidewall of said second type gate trench opposite to said first sidewall of said second type gate trench, connecting said PS1 region to said first body region;
said second body region has a doping concentration lower than that of said first body region;
a second gate electrode surrounded with a second insulating film on a bottom region of said second type gate trench, and with a second gate oxide on sidewalls of said second type gate trench; and said second gate oxide has an oxide thickness thinner than those of said second insulating film and said first gate oxide; and
said first and second body regions, said first and second source regions and said second gate electrode being shorted to a source metal.
